(19) United States
(12) Patent Application Publication
(10) Pub. No.: US 2025/0321392 A1
(43) Pub. Date: Oct. 16, 2025

(54) ELECTRICAL AND OPTICAL INTERCONNECT LINKS COMBINED IN A HYBRID INTERPOSER

(71) Applicant: Acorn Semi, LLC, Palo Alto, CA (US)

(72) Inventors: Paul A. Clifton, Redwood City, CA (US); Andreas Goebel, Mountain View, CA (US)

(21) Appl. No.: 19/177,180

(22) Filed: Apr. 11, 2025

Related U.S. Application Data
(60) Provisional application No. 63/632,958, filed on Apr. 11, 2024.

(51) Int. Cl. G02B 6/43; G02B 6/42; H01L 25/16; H10F 55/00

(52) U.S. Cl. CPC G02B 6/43; G02B 6/4212; G02B 6/4283; G02B 6/4295; H01L 25/167; H10F 55/18

(57) ABSTRACT

A hybrid photonic-electric interposer that includes an electrical part having electrical signal paths and a photonic part having photonic signal paths, with the electrical signal paths and the photonic signal paths being formed in parallel planes. The photonic part includes a plurality of sets of light emitting devices, waveguides, and photodetectors. In each one of said sets, the respective light emitting device, waveguide, and photodetector are coplanar with one another. In some instances, the photonic part may be disposed underneath the electrical part with the waveguides of the photonic part arrayed under metal interconnect layers of the electrical part and surrounded by a low refractive index dielectric. The light emitting devices of the photonic part may be light emitting diodes or lasers, and each of the light emitting devices may be configured to be modulated directly by an electrical signal to transmit photonic signals according to a non-return-to-zero modulation scheme.

### RELATED APPLICATIONS

This is a NONPROVISIONAL of and claims the priority benefit of U.S. Provisional Application 63/632,958, filed Apr. 11, 2024, which is incorporated by reference herein.

### FIELD OF THE INVENTION

The present invention relates to methods and systems for point-to-point interconnections within a die or chiplet or and/or interconnecting several dies or chiplets within a common package, and, more specifically, to electrical and optical links in a hybrid interposer.

### BACKGROUND

It is an increasing trend in high performance computing hardware for multiple integrated circuit die, or “chiplets,” to be packaged together and connected to form a system-in-package (SiP). Some of the latest, most advanced packages use a short electrical bridge to connect two reticle-limited dies into a unified processing element. Others employ 3D packaging with separate processing elements sharing a single pool of virtual and physical memory with low latency. Still, electrical signaling between points within such packages often requires traversing multiple bridges and many clock cycles. And most of the shoreline (die edge) of these modern die assemblies is being utilized for signaling between adjacent dies.

In addition to chip real estate, the power envelope of various interconnections is an important consideration. Off-package connections consume more than 3-5 pJ/bit in energy, and latency and jitter render multi-package systems asynchronous. On the other hand, electrical connections between chiplets inside a package can be synchronous, but must be quite short (˜1 mm at ˜1 pJ/bit) and can only connect directly adjacent dies. Longer electrical connections require SERDES. However, SERDES circuitry cannot be located just anywhere within a chip and, as the industry approaches reticle-limited die sizes, SERDES also takes away irreplaceable real estate.

Recently, it has been shown that synchronous within-package connections with less location restrictions can lead to a significant reduction in compute energy by enabling new architectures where the whole chip can remain synchronous. S. S. Iyer, V. Roychowdhury, “AI Computing reaches for the Edge,” Science, v. 382, pp. 263-264 (Oct. 20, 2023); D. S. Modha, et al., “Neural Interface at the Frontier of Energy, Space, and Time,” Science, v. 382, pp. 329-335 (Oct. 20, 2023). However, just like SERDES connections, electrical bridges operating at native CMOS logic frequencies using simple inverter-based transceivers (low power) still face a distance penalty, i.e., to transmit over more than a few millimeters requires larger (fewer) wires or results in lower data rates. See R. Mahajan, et al., “Embedded Multidie Interconnect Bridge A Localized, High-Density Multichip Packaging Interconnect,” IEEE Trans. Components, Packaging and Manufacturing Tech., v. 9, pp. 1952-1962 (October 2019).

Current co-packaged optical (CPO) approaches do not solve the power envelope nor the layout restrictions, as their connections to the information units (CPU, GPU, memory) remain electrical and are subject to the existing I/O layout rules and due to their limited number of channels (wavelengths) intrinsically require very high data rates. Conventional co-packaged optics using high data rates also cannot provide coherent, i.e., synchronous, connections. Furthermore, these CPO approaches are too temperature sensitive to be located underneath GPUs and CPUs with unpredictable workload and they are very expensive, closer to several hundred times the cost of electrical I/O when measured in $/Tbps.

### SUMMARY

Recognizing that in modem “Hybrid Integration” schemes there is a need for low-cost, low power, within-package short-and-long-distance interconnects with reduced I/O placement restrictions, the present invention provides, in various embodiments, a within-package optical solution that can connect directly from anywhere within one die to anywhere within another die over long distances, remain synchronous and provide good bandwidth at 1-2 Tbps/mm at low I/O power (e.g., less than or equal to approximately 1 pJ/bit, die-to-die).

One embodiment of the present invention provides a hybrid photonic-electric interposer that includes an electrical part having electrical signal paths and a photonic part having photonic signal paths, with the electrical signal paths and the photonic signal paths being formed in parallel planes. The photonic part of the interposer includes a plurality of sets of light emitting devices, waveguides, and photodetectors, wherein in each one of said sets, the respective light emitting device, waveguide, and photodetector are coplanar with one another. In some instances, the photonic part of the interposer may be disposed underneath the electrical part of the interposer with the waveguides of the photonic part of the interposer arrayed under metal interconnect layers of the electrical part of the interposer and surrounded by a low refractive index dielectric. The light emitting devices of the photonic part of the interposer may be light emitting diodes or lasers, and each of the light emitting devices may be configured to be modulated directly by an electrical signal to transmit photonic signals according to a non-return-to-zero modulation scheme.

Another embodiment provides an electronic device that includes a plurality of semiconductor dies, each having a number of circuit blocks, and a hybrid photonic-electric interposer, where the interposer and the dies are located within a common package. As indicated above, the hybrid photonic-electric interposer incorporates both a photonic part with photonic signal paths and an electrical part with electrical signal paths and the hybrid photonic-electric interposer is configured so as to transport data between various ones of the circuit blocks of the dies through both the photonic and electrical signal paths. The electrical signal paths and the photonic signal paths may be formed in parallel planes in the hybrid photonic-electric interposer. In some cases, the electrical part of the interposer overlies the photonic part of the interposer. One or more of the dies may comprise memory.

In various embodiments, within one or more of the dies, those of the circuit blocks of the dies that communicate through the photonic signal paths may be physically interspersed with others of the circuit blocks that communicate using the electrical signal paths.

In various embodiments, light emitting devices, waveguides, and photodetectors of the photonic part of the interposer may be coplanar and may have widths of approximately one micron.

In various embodiments, the photonic part of the interposer may be disposed underneath the electrical part of the interposer with photonic waveguides of the photonic part of the interposer arrayed under metal interconnect layers of the electrical part of the interposer. The photonic waveguides may be surrounded by a low refractive index dielectric, such as silicon dioxide.

In various embodiments, the hybrid photonic-electric interposer may be formed such that a silicon oxide layer is disposed below the photonic waveguides; the silicon oxide layer being, for example, a buried oxide layer of a silicon-on-insulator substrate.

In various embodiments, the photonic and electronic signal paths of the hybrid photonic-electric interposer may cross over one another.

In various embodiments, the photonic part of the interposer may include numerous parallel photonic signal paths, for example, a number of such signal paths sufficient to provide thousands or tens-of-thousands of point-to-point connections.

In various embodiments, the photonic part of the interposer may include one or more light emitting diodes arranged to transmit photonic signals according to a non-return-to-zero modulation scheme, with respective ones of the light emitting diodes configured to be modulated directly by respective electrical signals provided by respective circuits on a respective one of the dies.

In various embodiments, the electrical signal paths may be configured for relatively short distance signaling, e.g., between or within the circuit blocks of the dies, while the photonic signal paths may be configured for relatively long connections between the circuit blocks, e.g., of up to approximately 100 mm or more.

In various embodiments, light emitting devices, waveguides, and photodetectors of the photonic part of the interposer are manufactured within a common process flow as metal wires that make up the electrical part of the interposer.

In various embodiments, light emitting devices of the photonic part of the interposer are light emitting diodes (LEDs) or lasers and the light emitting devices may be configured to generate optical signals within a gain medium disposed locally within a semiconductor-on-insulator substrate. Further, the light emitting devices may be configured to each be directly modulated by respective electrical signals to generate respective ones of the optical signals, and waveguides of the photonic part of the interposer may be configured as single-wavelength point-to-point connections to route the respective optical signals to respective receivers. Also, photodetectors configured as the respective receivers of the photonic part of the interposer may be present to detect the respective optical signals and to each directly drive a respective receiver stage in receiving circuits.

### BRIEF DESCRIPTION OF THE DRAWINGS

The present invention is illustrated by way of example, and not limitation, in the figures of the accompanying drawings, in which,

FIG. 1 is a schematic cross-section through a conventional electrical interposer;

FIG. 2 illustrates a conventional electrical interposer between a transmitter and a receiver, in the form of a transmission line;

FIG. 3 illustrates an example of an Embedded Multidie Interconnect Bridge (EMIB);

FIG. 4 illustrates an equivalent circuit of a photonic communication link or NPCL in accordance with an embodiment of the present invention;

FIG. 5 illustrates an embodiment of an NPCL fabricated underneath metal interconnect layers in a hybrid photonic/electric interposer in accordance with an embodiment of the present invention;

FIG. 6 illustrates an example of a conventional electrical interconnect of arbitrary length between a pair of chips;

FIG. 7A illustrates a first example of a photonic interconnect between a pair of chips in accordance with an embodiment of the present invention;

FIG. 7B illustrates a second example of a photonic interconnect between a pair of chips in accordance with an embodiment of the present invention;

FIG. 7C illustrates a third example of a photonic interconnect between a pair of chips in accordance with an embodiment of the present invention;

FIG. 8 illustrates a comparative example of a hybrid photonic (NPCL) and electrical interposer/bridge in which SerDes and driver and amplifier circuits are employed in transmitting data through both photonic (NPCL) and electrical signal paths in the hybrid interposer in accordance with an embodiment of the present invention;

FIG. 9 illustrates an example of a combination of photonic (NPCL) and electrical interposers/bridges in which no SerDes is employed while driver and amplifier circuits are included in transmitting data through both photonic (NPCL) and electrical signal paths in the hybrid interposer in accordance with an embodiment of the present invention; and

FIG. 10 illustrates an example of a combination of photonic (NPCL) and electrical interposers/bridges wherein no SerDes or driver or amplifier circuits are employed in transmitting data through both photonic (NPCL) and electrical signal paths in the hybrid interposer in accordance with an embodiment of the present invention.

### DETAILED DESCRIPTION

In one embodiment, the present invention provides an in-package, nano-photonic communication layer (NPCL) that can operate at low power (e.g., less than or equal to approximately 1 pJ/bit, die-to-die), transmit signals at rates of at least approximately 2 Gpbs (and, in some embodiments, closer to approximately 4-8 Gbps) per waveguide at competitive bit error rates over distances of 10 to 100 s mm within a package. The I/O pins can be located throughout the main die area, not just at the beachfront. The optical signals are generated within a gain medium furnished locally within a silicon-on-insulator (SOI) substrate, where the optical emitter is directly modulated by a native speed data processor or memory (low GHz-range), and where the optical signal is routed to the receiver using waveguides that provide single-wavelength point to point connections, where the signal is detected by an optical detector that directly drives a receiver stage in the receiving data processor or memory.

This invention addresses the needs identified above. By enabling a new, faster, more capable, lower power and larger package it substantially expands the design envelope for hybrid integration of multi-die leading edge data processing units. For example, multiple graphics processing units (GPUs), as used in AI-related compute systems. Or combinations of GPUs and central processing units (CPUs) as used in high performance computing (HPC) systems.

The interposer can be made of a silicon (Si), an organic material or glass. However, a Si interposer is preferred as it enables a higher density of interconnects, through-silicon vias (TSVs) and micro-bumps to be patterned.

In one embodiment of the invention, an in-package nano-photonic communication layer (NPCL) is combined with an electric interposer or bridge. The NPCL is typically formed beneath the metal layers that comprise the electrical interposer or bridge. Electrical interfaces are accomplished with conventional electrical interposer components, such as metal traces, hybrid bonded and TSVs.

The NPCL can operate at low power (<≅1 pJ/bit, die-to-die), transmit signal at rates of at least 2 Gpbs (preferably closer to 4-8 Gbps) per waveguide at competitive bit error rates over distances of 10 to 100's mm within a package. The I/O pins can be located throughout the main die area, not just close to the edge of a die (the “beachfront”). The optical signals are generated within a gain medium furnished locally within a silicon-on-insulator (SOI) substrate, where the optical emitter is directly modulated by a native speed processor or memory (low GHz-range) to generate an optical signal, the optical signal is routed to the receiver using waveguides that provide single-wavelength point to point connections, and at the receiver the signal is detected by a photodetector that directly drives a receiver stage in the receiving processor or memory.

The transmit and receive circuits are ideally based on series of inverters and are located in the electronic die that are attached to the interposer. There are no transistors in the interposer itself. Moreover, the system has no external light sources or fiber connectors, thus avoiding difficult packaging steps that adversely impact cost and yield. The light emitters may be manufactured within the process flow. Emitters need not be attached or connected as they are in other optical I/O approaches. Detectors may also be manufactured as part of the same process flow. A very wide parallel connection is able to provide thousands or tens-of-thousands of point-to-point connections and need not employ electrical SERDES approaches together with optical multiplexing to achieve a very high bandwidth. The NPCL approach is designed to be temperature insensitive, power efficient, and exhibits only a negligible power penalty for longer distances. NPCL eliminates the need for highly tuned optical resonators that are extremely temperature sensitive. Our approach is cost-effective, estimated to be around 2-5 times the cost of electrical bridges, while today's co-packaged optics that uses external lasers, temperature stabilization and multiplexing are closer to 200-500 times the cost per bandwidth of electrical bridges. Stojanovic, V., “Understanding In-Package Optical I/O Versus Co-Packaged Optics,” Photonics Spectra, v. 50, no. 3, pp. 45-49 (March 2024).

The NPCL system uses light emitting devices to transmit data from one point on a die to another point on the same die or to a point on another die in the same package. The die may be a compute die such as a CPU or GPU or a memory device or any other chiplet, such as an I/O die or co-packaged optics (CPO) die that transmits data off package. Light emitting devices, such as light emitting diodes (LEDs) or lasers, and photodetectors (PDs) in the NPCL are coplanar within the NPCL and may be manufactured within the same process flow as the metal wires that comprise the electrical bridge or interposer. The NPCL system has no external light sources or fiber connectors, thus avoiding difficult packaging steps that adversely impact cost and yield. Light emitting devices are not attached or connected as they are in other optical I/O approaches.

Active die are attached to the interposer using microbumps, as is the manufacturing standard for such heterogeneous systems currently. The waveguides, light emitting devices and photodiodes have widths of around one micron and are therefore compatible with future hybrid bonding connections that are anticipated to also be sized around one micron.

No ESD protection devices are required to protect the active die during the die attachment process. Elimination of ESD protection is important for minimizing the capacitance (i) between the last inverter in the transmitter and the light emitting device and (ii) between the photodiode and the first inverter in the receiver.

In order to provide a large data bandwidth, the NPCL is configured to have a very large number of parallel photonic signal paths able to provide thousands or tens-of-thousands of point-to-point connections distributed across a die. Signaling is preferably non-return-to-zero wherein the transmitting LED is modulated directly by an electrical signal provided by the circuit on an attached die. The use of massively parallel signal paths importantly enables power-hungry and chip area consuming serialization/deserialization (SERDES) circuitry to be avoided in the attached die.

Being an optical communication system, NPCL exhibits only a negligible power penalty for transmission of data over long distances. It is anticipated that NPCL will enable interconnection of co-packaged die spaced far apart in future large packages containing many heterogeneous die (also termed chiplets in this context), some of which may be large (e.g., as large as the lithography reticle size limit).

The NPCL is preferably an incoherent optical system allowing it to be relatively temperature insensitive and power efficient, compared to coherent laser-based photonic interconnect systems. NPCL eliminates the need for highly tuned optical resonators that are used in coherent photonic interconnects and are extremely temperature sensitive. Our approach is cost-effective, estimated to be around 2-5 times the cost of electrical bridges, while today's co-packaged optics that uses external lasers, temperature stabilization and multiplexing are closer to 200-500 times the cost per bandwidth of electrical bridges.

The NPCL may be manufactured in a low-cost integration scheme that utilizes CMOS compatible materials such as epitaxial Ge and GeSn-alloys, and chemical vapor deposited SiN stressors, in combination with silicon-on-insulator (SOI) wafers. The patterning critical dimension (CD) requirements are around ˜80 nm and, as a result, regular and depreciated CMOS fabs can be employed for its manufacture. The integration scheme relies on common CMOS-like process steps and avoids costly and yield-impacting schemes that involve pick-and-place of gain material or finished photonic devices. The present assignee's U.S. Pat. No. 8,731,017 B2 features the local alteration of the band structure of germanium and germanium alloys through the integration of local stressor materials and to utilize these strained areas as gain material in light emitters as well as using it as absorbing material with a narrower bandgap in a photodetector, all integrated as part of the same integrated process flow. Accordingly, the materials and techniques described in the '017 patent may be employed in connection with the fabrication of the present NPCL.

As noted, waveguide pitches of approximately 3-5 μm, micro-bump pitches of approximately 40-60 μm and hybrid bonding pitches of approximately 1 μm may be used. Simply put, the reason is that the wavelength of light for which semiconducting materials or dielectrics derived from semiconductor materials are transparent is closer to about 1 μm. Confining that light using refractive index difference requires a feature size (such as waveguide width) around at least half that wavelength, i.e., at least 0.5 μm. Highly confined light in densely spaced adjacent waveguides can leak into adjacent features such that, for good isolation, waveguide features denser than a 2 μm pitch may not be desirable, although in some cases waveguide features denser than on a 2 μm pitch may be used if a thin cladding is used or if some amount of leakage is deemed acceptable.

One embodiment of an NPCL in accordance with the present invention is a drop-in replacement of existing within-package electrical bridges in an existing product. For example, the electrical bridge (CoWoS) in Advanced Micro Devices' Versal™ chip, which interconnects four large programmable dies in quadrants, may benefit from an NPCL deployed between the outer corners of diagonally opposed dies. Signals between these corners currently have to traverse two electrical bridges and long, on-die or in-package electrical lines that are power hungry and prone to cross-talk resulting in latency. NPCLs can connect these far corners within a package without SERDES, coherently, i.e., far removed logic gates can be connected to communicate at low power within a clock-cycle.

Electrical interposer schemes require about every other wire to be a grounded conductor to isolate against crosstalk. Photonic waveguides do not require such an interspersed “active” isolation, easily doubling their useful connection density. Most advantageously, however, our nano-photonic communication layer can be combined straight-forwardly with additional layers of conventional electrical within-package signaling, for example CoWoS, so that the existing design space is merely added to by our approach. We are providing additional capability to existing or to be developed electrical solutions.

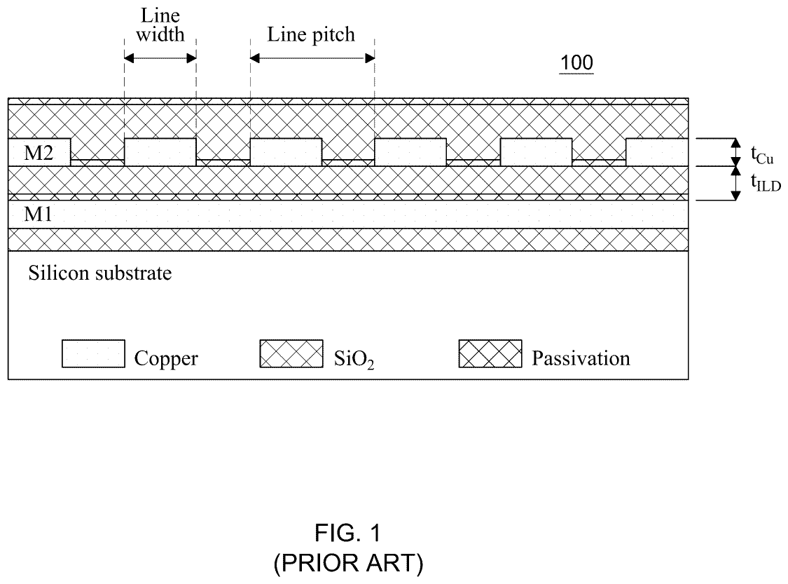

Conventional Si interposers typically comprise two copper metal layers and one aluminum redistribution layer (A1 RDL). FIG. 1 shows a schematic cross section through a typical electrical interposer 100. The interconnection lines are in a micro-strip configuration, where the first metal layer, M1, is dedicated to power and ground routing, while the second metal layer, M2, is used for data signaling between the active dies. For the sake of simplicity, the RDL layer has not been represented. Interconnect (signal) lines have a thickness between 500 nm and 2 μm, a width between 350 nm and 6 μm and their minimum spacing is 350 nm.

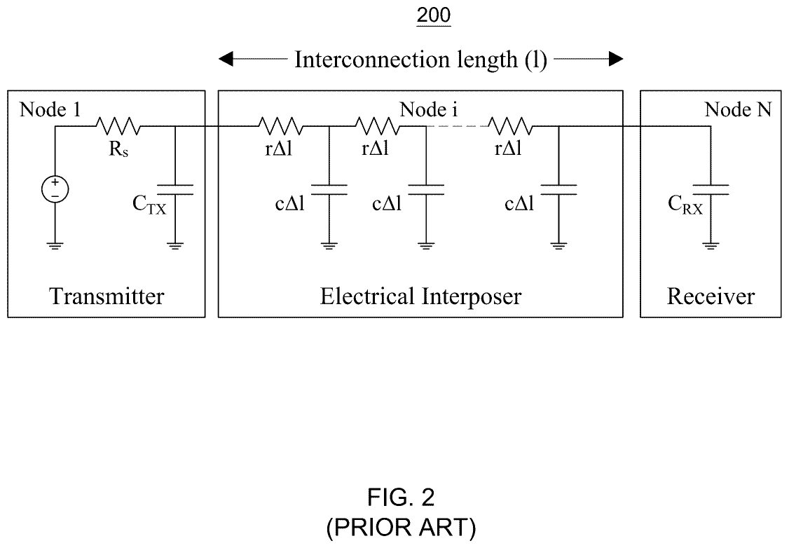

FIG. 2 shows the equivalent circuit of a typical interposer communication link 200. It is composed of three lumped elements:
a. R_{S} is the output resistance of the transmitter 202 and depends on its drive strength. The higher the drive strength, the lower the output resistance and the higher the current the transmitter is able to drive. The strongest driver defined in the HBM2 standard has a nominal output current of 18 mA, and operates with a voltage swing of 1.2 V, which yields R_{S}˜66Ω.
b. C_{TX} and C_{Rx} are lumped capacitances representing the total output capacitance of the transmitter 202 and the receiver 204, respectively, and include any ESD protection, micro-bumps and transceiver capacitances. Typical 40 μm pitch micro-bumps have a self-capacitance of approximately 15 fF. If the link is half-duplex, C_{TX} and C_{RX} are equal and have a default value of 200 fF.
c. r and c are the distributed resistance and capacitance per unit length (Dl) of the lines.

The receiver 204 is a chain of inverters that amplifies and restores the voltage signal detected at Node N. The maximum bit rate=1/t_{RX} where t_{RX} is the Elmore RC delay to change the output signal value from 0% to 90% of its final value given as:

$${τ}_{R X} = 2.3 [ {R}_{S} ( {C}_{T X} + c \cdot l + {C}_{R X} ) + r \cdot {C}_{R X} \cdot l ] + r \cdot c \cdot {l}^{2}$$

and l is the total length of the line. It can be seen in this equation that the RC delay can be a strong function of l if r and/or c is significant. Typically, this leads to a rapidly declining maximum bit rate capability when electrical lines extend beyond a few mm.

Short electrical interconnects (1 mm), generally used in logic-to-logic links, make it possible to reach bandwidth densities as high as 4.2 Tbps/mm (terabits per second per mm of die edge or “shoreline”). A 1 mm interconnect line typically consumes 0.37 pJ/bit at 8.4 Gbps. Longer electrical interconnects (e.g., 7 mm), typical of logic-to-memory links, are only able to achieve bandwidth densities up to 710 Gpbs/mm and typically consume 0.76 pJ/bit at a transmission rate of 2.5 Gbps.

In future high performance systems directed at artificial intelligence (AI) and high performance computing (HPC) even longer data links are anticipated between die within a package, possibly extending as long as 100 mm. Such links cannot be reasonably serviced by electrical wires.

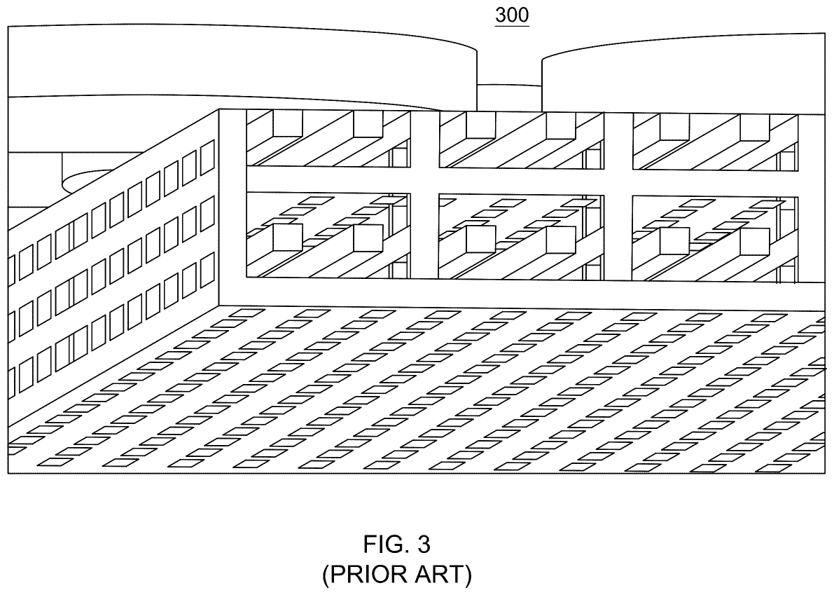

An example of a state-of-the-art interposer with high performance is an Embedded Multidie Interconnect Bridge (EMIB) 300, illustrated in FIG. 3, which is an Intel proprietary technology. EMIB provides very short links between closely spaced adjacent die and as such is known as a bridge rather than a full interposer. EMIB may have pairs of coplanar transmission lines surrounded by metal ‘cages’ for lateral and vertical isolation and avoidance of crosstalk.

EMIB and similar bridges such as CoWoS (developed by TSMC and Xilinx) offer high bandwidth by virtue of having many electrical signal lines per mm of die edge (shoreline), the lines being arranged in two layers and providing on the order of 1,000 input/output (I/O) traces per mm.

A 1200-I/O per mm bridge die with narrow and thin metal wires operating at ˜3 Gb/s achieves a very high data bandwidth density of 3.6 Tb/s/mm. Such a bridge has around 1.5 mm maximum reach and as such is suitable only for connecting closely-spaced adjacent die, for example two GPUs or a GPU and a CPU.

A 300-I/O per mm bridge die having thicker metal wires may have 5 mm reach and operate at 5 Gb/s, achieving a data bandwidth density of 1.5 Tb/s/mm.

For even longer reaches such as 25 mm the preferred solution is to route metal traces through a standard organic substrate and operate the I/O at elevated bit rates. Such a scheme would typically comprise 40-I/O traces per mm, each operating at 25 Gb/s, for 1 Tb/s/mm of data bandwidth density. However, this requires more sophisticated transceiver circuits including serialization/deserialization (SerDes), retiming and signal conditioning circuits, all of which consume significant electric power and expensive chip area. Considering the intention of the multi-die approach to system integration is to utilize small area chiplets for higher yield and lower cost, it is highly counterproductive to impose a requirement for sophisticated I/O circuitry that can end up occupying a large share of the chiplet area.

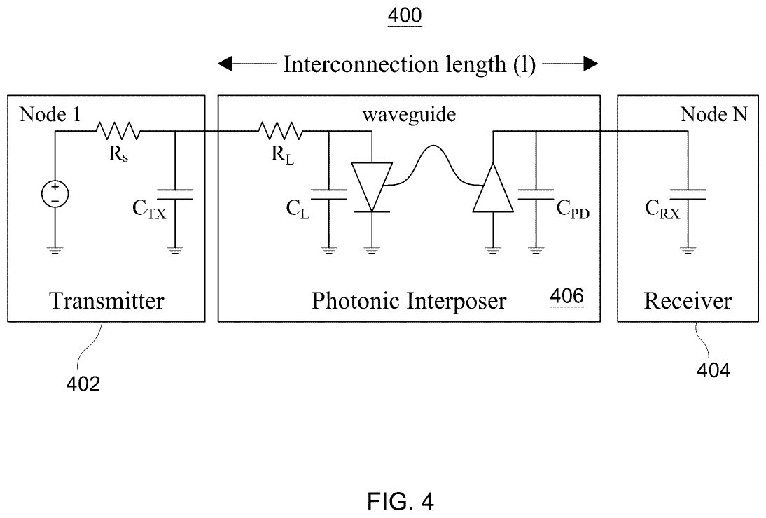

FIG. 4 shows the equivalent circuit of the proposed photonic communication link or NPCL 400. The r and c of an electrical interposer are now absent as there is no electrical wire linking the transmitter 402 and receiver 404. It has been replaced by a light emitting device (light emitting diode or laser) at the transmitter end of the interposer 406 and a photodiode at the receiver end with an optical waveguide communicating the data as an optical signal between the two. The link is an optical waveguide which has no r or c.

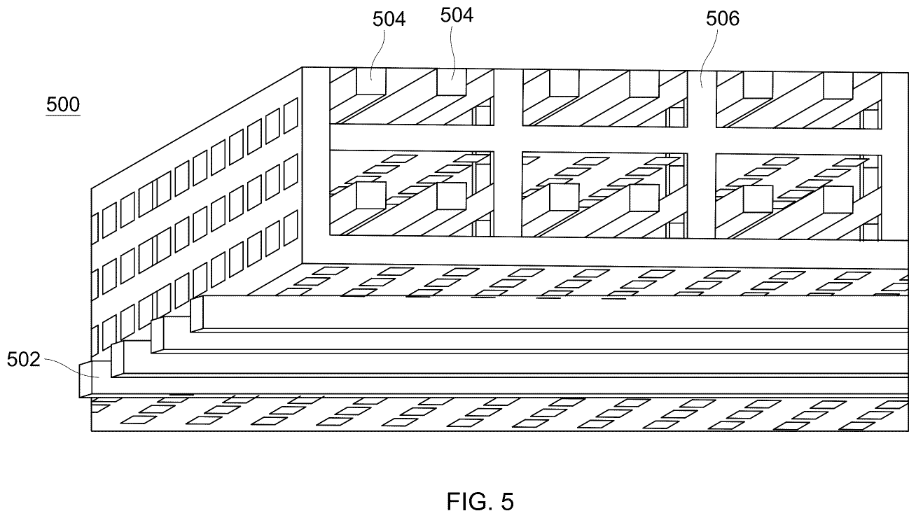

The NPCL is preferably fabricated underneath the metal interconnect layers as shown in the example of a hybrid photonic/electric interposer 500 in FIG. 5. This illustrative example shows photonic waveguides 502 arrayed under the metal interconnect layers of an EMIB type of bridge. The EMIB signal traces are in pairs 504 and surrounded by a metal cage 506. The waveguides 502 are surrounded by low refractive index dielectric such as silicon dioxide (not shown). The silicon oxide underneath the waveguides is preferable a buried oxide (BOX) layer of a semiconductor-on-insulator (SOI) substrate (not shown).

The strongest driver defined in the HBM2 standard has a nominal output current of 18 mA and operates with a voltage swing of 1.2 Volt.

The new industry standard for UCIe strongly recommends that chiplets adopt a transmitter voltage less than 0.85 V so that they can inter-operate with a wide range of process nodes in the foreseeable future.

Assuming an LED operates with a voltage swing of 0.8 V and requires a 5 mA drive current to output 100 μW of optical power into the waveguide (a 2.5% external efficiency), the LED input power when emitting is 4 mW. Running the photonic link at 4 Gbps, that translates to 1 pJ per bit. As such, the NPCL has an energy efficiency per transmitted bit that is similar to the energy efficiency of a short electrical bridge (e.g., on the order of 1 mm long).

The benefit of the NPCL is not necessarily to achieve greater efficiency for shorter signal paths less than 10 mm but rather to enable much longer signal paths of 100 mm length, or even more, between distant die located in the same package. Long signal paths may arise for example when a processor die such as a GPU is connected to a large number of memory die distributed around but not proximate to the processor. Memory die may include high bandwidth memory (HBM) or faster static random access memory (SRAM). SRAM is fast but of low density and currently occupies a large fraction of processor die area because it must be located close to the logic circuits. Large SRAM blocks on processor die are wasteful of very high cost logic area. High performance computing processors such as GPU, CPU or tensor processors for AI applications are typically fabricated in the most advanced and most expensive CMOS logic process available at a given time. SRAM on the other hand does not scale with the node size and thus occupies an increasingly large fraction of the logic die. NPCL provides high bandwidth and low-latency photonic connections between logic and SRAM that enables SRAM to be provided in the system package in separate die, not even adjacent to the logic (processor) die. This enables systems to be architected in a package with (i) much more SRAM per processing unit, (ii) at a much lower cost as the SRAM can be built in a lower cost technology node, while (iii) the SRAM appears to the logic circuitry to be local with no loss of memory access performance.

Alternatively, NPCL enables multiple processor die to be located non-adjacent in a package while still connected together coherently, such that they share a common clock as if they were formed within the same die and acting synchronously. It may be advantageous for example to locate high power processor die spaced apart within the package to enable better heat distribution.

As used herein, the term “die” is used interchangeably with the term “chip” and the term “bridge” is used interchangeably with the term “interposer” with the understanding that “interposer” does not imply any particular length scale for the length of interconnect lines while the term “bridge” generally implies a short interconnect system, spanning maybe 1-2 mm between the edges of adjacent, closely spaced die. An interposer does not necessarily transmit electric signals between adjacent die edges as an interposer may have lines with sufficient reach to connect any part of one die to any part of another die. The term LED (light emitting device) may imply a directly modulated light emitting diode or laser or even a directly modulated nanophotonic light emitting diode or laser, where nanophotonic implies having parts that are nanometer scale, i.e., being less than a micron or approximately one micron in extent.

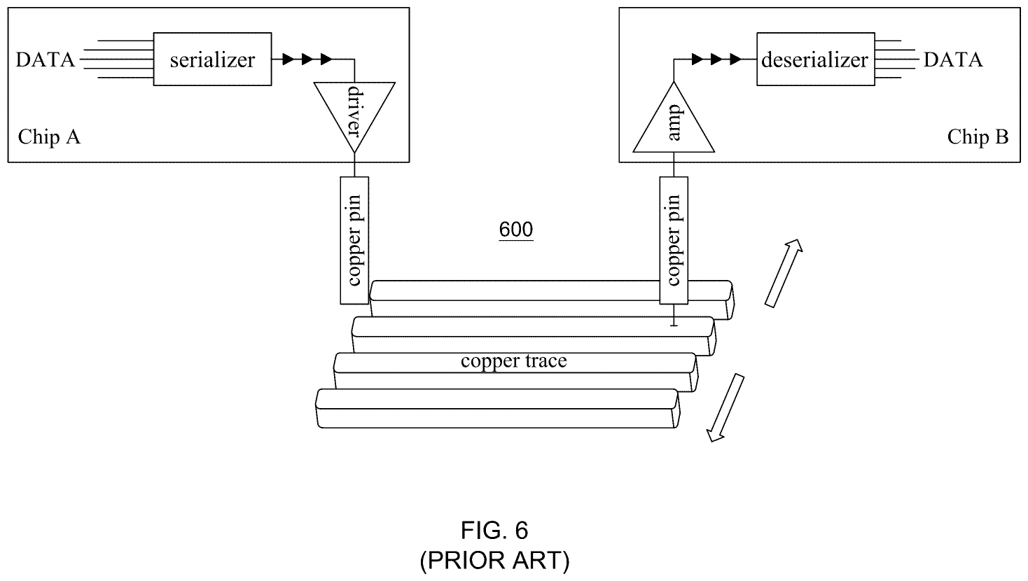

FIG. 6 represents a conventional embodiment of electrical interconnect 600 of arbitrary length between Chip A (which may be a CPU, GPU, TPU or memory chip) and Chip B (which also may be a CPU, GPU, TPU or memory chip). In this embodiment a parallel data stream to be transmitted is serialized and then transmitted through a driver circuit to a horizontal copper trace via a metal connection which may include a microbump or hybrid bonded copper connection and/or a copper pin. The copper traces in this example (of which there may be many, e.g., up to 10,000 or more) may correspond to the metal traces depicted in FIG. 1 or the transmission lines depicted in FIG. 2. At the receiver the serial data stream is passed to Chip B via a similar metal connection which may include a microbump or hybrid bonded copper connection and/or a copper pin. At Chip B the serial data signal passes through an amplifier, ‘amp’, and then into a deserializer wherein the original parallel data stream is restored. There may be a plurality of copper traces connecting drivers in Chip A with amps in Chip B and a similar number of traces in the reverse direction connecting drivers in Chip B with amps in Chip A (not shown).

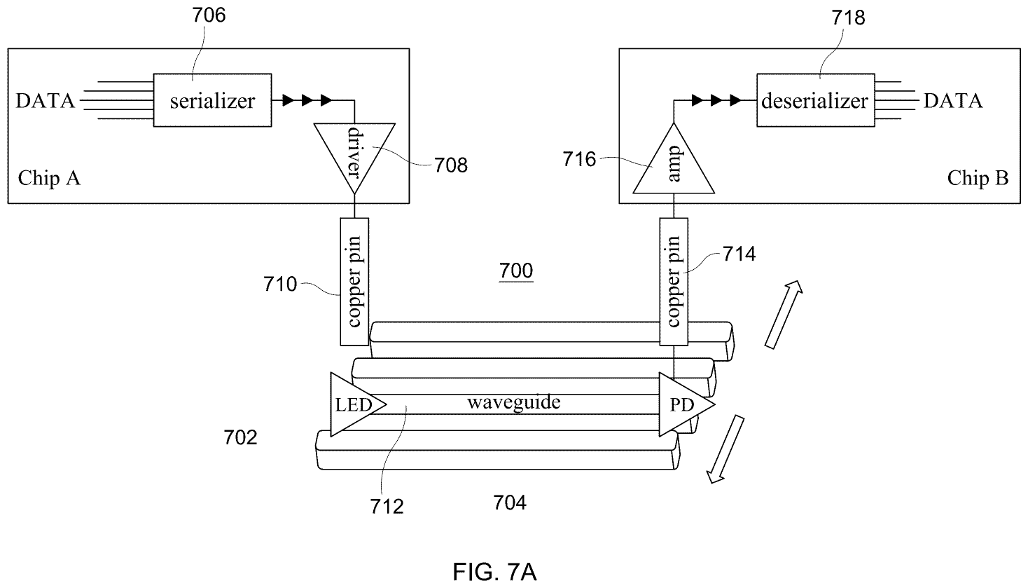

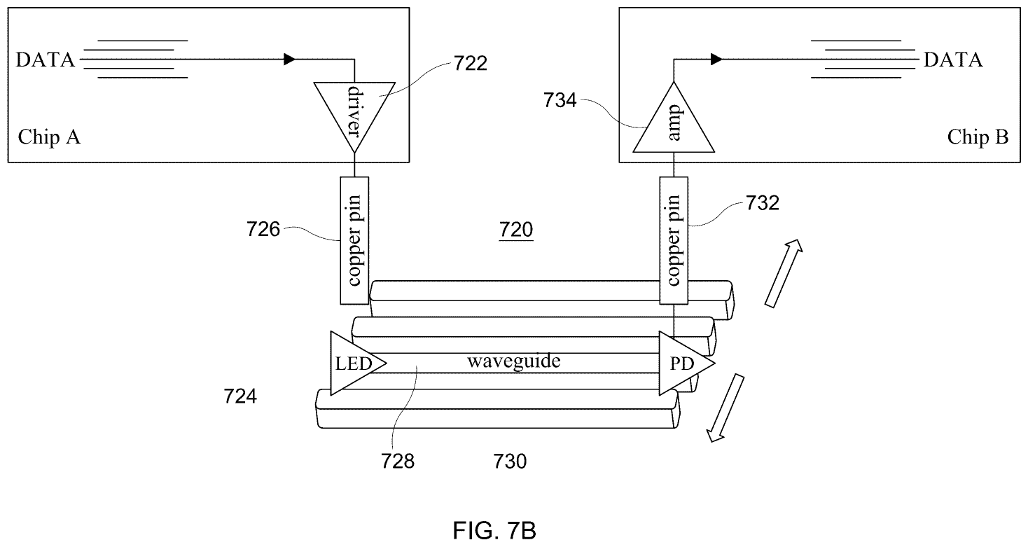

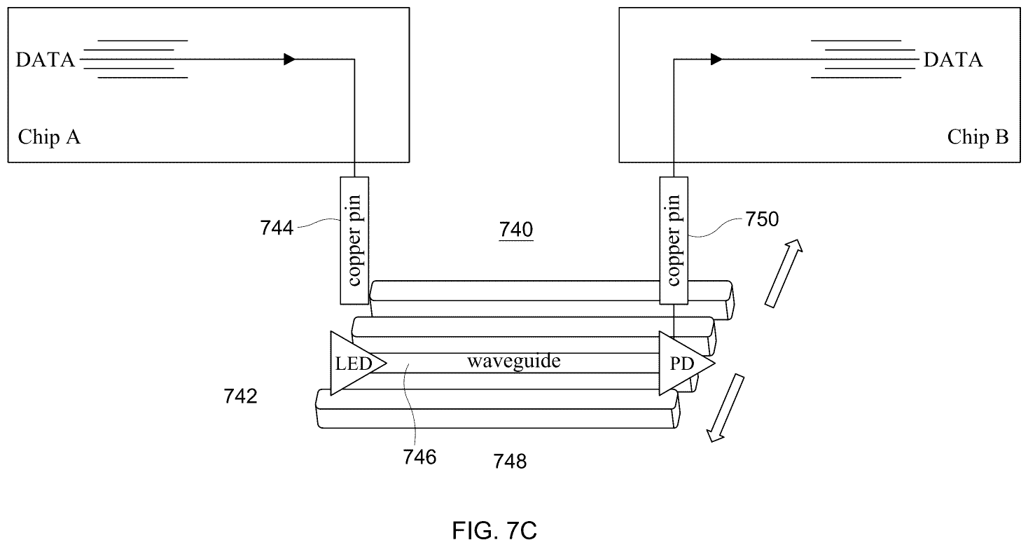

FIG. 7A represents one embodiment of the present invention: a photonic interconnect 700 between Chip A (which may be a CPU, GPU, TPU or memory chip) and Chip B (which also may be a CPU, GPU, TPU or memory chip). In this embodiment a parallel data stream to be transmitted is serialized and then transmitted through a driver circuit to a light emitting device (LED) 702 via a metal connection which may include a microbump or hybrid bonded copper connection and/or a copper pin. The LED 702 may preferably be a directly modulated nanophotonic light emitting device. The serializer 706 and driver 708 in Chip A may be essentially the same specification and design as the serializer and driver in Chip A of the conventional electrical bridge example in FIG. 6, as may be the metal connection 710 which may include a microbump or hybrid bonded copper connection and/or a copper pin. The LED 702 generates an optical signal corresponding to the electrical signal provided by the driver 708 in Chip A and that optical signal is transmitted through a waveguide 712 (of which there may be many, e.g., up to 10,000 or more). The LED 702 is preferably edge-emitting and is located in the same plane as the waveguide 712 such that there is an efficient transmission of the light emitted by the LED into the waveguide. It may be said that the LED 702 is preferably “waveguide-embedded.” Ideally the LED 702 includes a mirror structure to prevent light passing in a direction contrary to the intended transport direction along the waveguide 712. At some point along the waveguide 712, which may be less than 1 mm or more than 10 mm away from the LED, a wavelength-matched, nanophotonic photodetector (PD) 704 detects the optical signal. The PD 704 is preferably located in the same plane as the waveguide 712 such that there is an efficient transmission of light from the waveguide into the PD. It may be said that the PD 704 is preferably “waveguide-embedded.” The output of the PD 704 is transmitted electrically as a serial data stream through a similar metal connection 714 which may include a microbump or hybrid bonded copper connection and/or a copper pin to Chip B. At Chip B the serial data signal passes through an amplifier 716 (“amp”), and then into a deserializer 718 wherein the original parallel data stream is restored. The amplifier 716 may be a transimpedance amplifier (TIA) to convert a current output from the PD 704 to a voltage signal of sufficient magnitude that it can drive a first stage of a circuit such as the deserialization circuit. Or the amplifier 716 may be a sense amplifier (SA) to convert a small voltage output signal from the PD 704 to a voltage signal of sufficient magnitude that it can drive a first stage of a circuit such as the deserialization circuit. A voltage output signal may be generated out of the PD 704 by including a resistive element of sufficient resistance between the PD and ground. A small output current generated by the PD 704 is converted to a small voltage signal by forcing that current through a suitably large resistor. There may be thousands of, or even in excess of ten thousand LEDs 702 with corresponding waveguides 712 and PDs 704 connecting drivers in Chip A with very many amps in Chip B. The large number of LEDs, waveguides and PDs provide a large bandwidth for photonic data transport between Chip A and Chip B. There may be a similar number of LEDs 702, waveguides 712 and PDs 704 providing a large bandwidth for data transport in the reverse direction between Chip B (which would require a driver circuit in Chip B corresponding to each LED, not shown) and Chip A (which would require an amp circuit in Chip B to receive the signal corresponding to each PD, not shown). A common ground is established between the driver circuit 710 of Chip A, the amplifier circuit 716 of Chip B and the LED 710 and PD 704 of the photonic interposer 700 (not shown).

FIG. 7B represents another embodiment of the present invention: a photonic interconnect 720 between Chip A (which may be a CPU, GPU, TPU or memory chip) and Chip B (which also may be a CPU, GPU, TPU or memory chip). In this embodiment a parallel data stream to be transmitted is not serialized. Instead, each separate data stream is transmitted through a driver circuit 722 to a light emitting device (LED) 724 via a metal connection 726, which may include a microbump or hybrid bonded copper connection and/or a copper pin. The LED 724 may preferable be a directly modulated nanophotonic light emitting device. The driver 722 in Chip A may be essentially the same specification and design as the driver in Chip A of the conventional electrical bridge example, as may be the metal connection 726 which may include a microbump or hybrid bonded copper connection and/or a copper pin. The LED 724 generates an optical signal corresponding to the electrical signal provided by the driver in Chip A and that optical signal is transmitted through a waveguide 728 (of which there may be many, e.g., up to 10,000 or more). The LED 724 is preferably edge-emitting and is located in the same plane as the waveguide 728 such that there is an efficient transmission of the light emitted by the LED into the waveguide. It may be said that the LED 724 is preferably “waveguide-embedded.” Ideally the LED 724 includes a mirror structure to prevent light passing in a direction contrary to the intended transport direction along the waveguide. At some point along the waveguide 728, which may be less than 1 mm or more than 10 mm away from the LED, a wavelength-matched, nanophotonic photodetector (PD) 730 detects the optical signal. The PD 730 is preferably located in the same plane as the waveguide 728 such that there is an efficient transmission of the light from the waveguide into the PD. It may be said that the PD 730 is preferably “waveguide-embedded.” The output of the PD 730 is transmitted electrically as a data stream through a similar metal connection 732 which may include a microbump or hybrid bonded copper connection and/or a copper pin to Chip B. At Chip B, the data signal passes through an amplifier 734 (“amp”), and then into the first stage of electronic circuitry in Chip B with no deserializer. The amplifier 734 may be a transimpedance amplifier (TIA) to convert a current output from the PD 730 to a voltage signal of sufficient magnitude that it can drive a first stage of a circuit such as a CMOS logic circuit. Or the amplifier 734 may be a sense amplifier (SA) to convert a small voltage output signal from the PD 730 to a voltage signal of sufficient magnitude that it can drive a first stage of a circuit such as a CMOS logic circuit. A voltage output signal may be generated out of the PD 730 by including a resistive element of sufficient resistance between the PD and ground. A small output current generated by the PD 730 is converted to a small voltage signal by forcing that current through a suitably large resistor. There may be thousands of, or even in excess of ten thousand LEDs 724 with corresponding waveguides 728 and PDs 730 connecting drivers 722 in Chip A with very many amps 734 in Chip B. The large number of LEDs, waveguides and PDs provide a large bandwidth for photonic data transport between Chip A and Chip B. There may be a similar number of LEDs, waveguides and PDs providing a large bandwidth for data transport in the reverse direction between Chip B (which would require a driver circuit in Chip B corresponding to each LED, not shown) and Chip A (which would require an amp circuit in Chip B to receive the signal corresponding to each PD, not shown). A common ground is established between the driver circuit 722 of Chip A, the amplifier circuit 734 of Chip B and the LED 724 and PD 730 of the photonic interposer 720 (not shown).

FIG. 7C represents another embodiment of the present invention: a photonic interconnect 740 between Chip A (which may be a CPU, GPU, TPU or memory chip) and Chip B (which also may be a CPU, GPU, TPU or memory chip). In this embodiment a parallel data stream to be transmitted is not serialized and the electrical signal is not amplified on either the transmitting or receiving side. Instead, each separate data stream is transmitted directly to a light emitting device (LED) 742 via a metal connection 744, which may include a microbump or hybrid bonded copper connection and/or a copper pin. The LED 742 may preferably be a directly modulated nanophotonic light emitting device. The metal connection 744, which may include a microbump or hybrid bonded copper connection and/or a copper pin, may be essentially the same specification and design as in the electrical bridge example of FIG. 6. The LED 742 generates an optical signal corresponding to an electrical signal provided by Chip A and that optical signal is transmitted through a waveguide 746. The LED 742 is preferably edge-emitting and is located in the same plane as the waveguide 746 (of which there may be many, e.g., up to 10,000 or more) such that there is an efficient transmission of the light emitted by the LED into the waveguide. It may be said that the LED 742 is preferably “waveguide-embedded.” Ideally the LED 742 includes a mirror structure to prevent light passing in a direction contrary to the intended transport direction along the waveguide. At some point along the waveguide 746, which may be less than 1 mm or more than 10 mm away from the LED, a wavelength-matched, nanophotonic photodetector (PD) 748 detects the optical signal. The PD 748 is preferably located in the same plane as the waveguide 746 such that there is an efficient transmission of the light from the waveguide into the PD. It may be said that the PD 748 is preferably “waveguide-embedded.” The output of the PD 748 is transmitted electrically as a data signal through a similar metal connection 750, which may include a microbump or hybrid bonded copper connection and/or a copper pin to Chip B and therein passes directly to drive a first stage of a circuit such as a CMOS logic circuit. There may be thousands of, or even in excess of ten thousand LEDs 742 with corresponding waveguides 746 and PDs 748 connecting Chip A with Chip B. The large number of LEDs, waveguides and PDs provide a large bandwidth for photonic data transport between Chip A and Chip B. There may be a similar number of LEDs, waveguides and PDs providing a large bandwidth for data transport in the reverse direction between Chip B and Chip A.

As illustrated in FIGS. 7A-7C, each waveguide connects a light source at the transmitter end of a data path with a photodetector at the receiver end of the same data path. The light source may be a LED or laser. The light source is preferably a LED that emits incoherent light. The light source is directly modulated by a signal provided at the transmitter by an electronic circuit that is attached to the interposer by metal (preferably copper) plugs. All of the optical components in the NPCL, the emitters, waveguides and detectors are contained in the same layer as the waveguides.

A photonic interposer or bridge does not have to be separate from an electrical interposer or bridge. On the contrary it may be cost-effective to fabricate some form of electrical interposer or bridge on top of and within the same structure as the photonic interposer. Such a hybrid photonic-electric interposer is also of great value as it increases the total data bandwidth serviced and provides additional advantages. In addition to providing a much larger aggregate data bandwidth, a hybrid photonic-electric interposer enables crossovers of photonic and electronic signal paths. In addition, electrical signal paths can be favorably assigned to short distance signaling needs between dies/chiplets or within a single die or chiplet. While photonic signal paths can be favorably assigned to long distance connections between die/chiplets that are relatively distantly separated within a package, up to 100 mm or so.

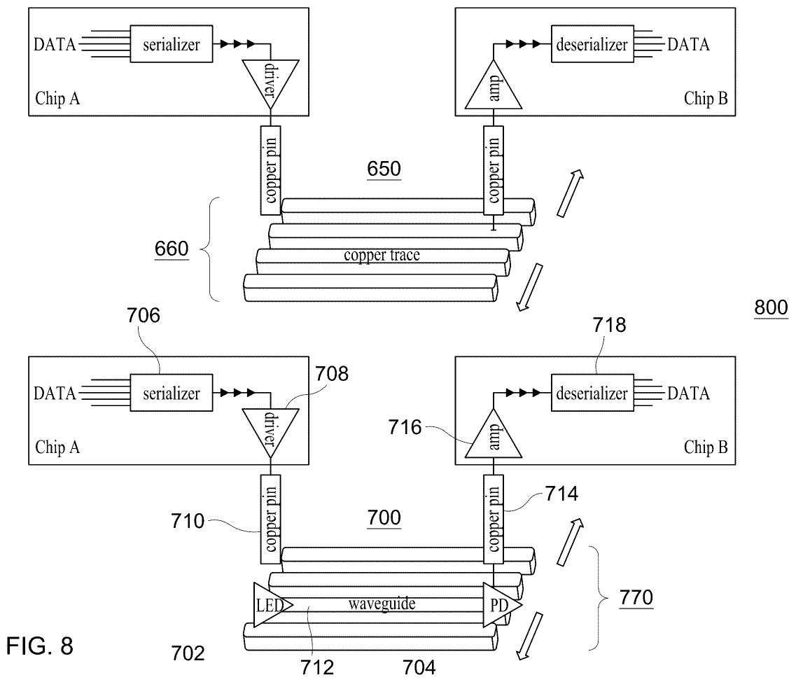

Various combinations of photonic (NPCL) and electrical interposers/bridges are illustrated in FIGS. 8, 9 and 10. As illustrated, all the NPCL components are conceptually located underneath the electrical interconnect layers as this is the way hybrid interposers are typically fabricated, with the copper traces (transmission lines) being formed after the photonic waveguides.

FIGS. 8, 9, and 10 schematically represent various embodiments of a hybrid photonic (NPCL) and electrical interposer/bridge wherein data is transmitted through both photonic (NPCL) 700, 720, 740 and electrical 650 signal paths in the hybrid interposer 800, 900, 1000. While the photonic and electrical parts of the combined, hybrid interposer are represented here as separate blocks, the electrical (copper trace) 660 and photonic (waveguide) 770 signal paths are physically formed in parallel planes in the same interposer and the two blocks corresponding to Chip A are physically contained within the same entity “Chip A.” Similarly, the two blocks corresponding to Chip B are physically contained within the same entity “Chip B.” Indeed, the circuit blocks that correspond with photonic interposer layer NPCL may be physically interspersed with circuit blocks that correspond with an electrical interposer layer or layers. Similarly, the copper pins and associated microbumps or hybrid copper bonded connections that correspond with photonic interposer layer NPCL may be physically interspersed with copper pins and associated microbumps or hybrid copper bonded connections that correspond with an electrical interposer layer or layers.

FIG. 8 represents an embodiment of a hybrid photonic (NPCL) and electrical interposer/bridge 800 wherein SerDes and driver and amplifier circuits are employed in transmitting data through both photonic (NPCL) 700 and electrical 660 signal paths in the hybrid interposer 800.

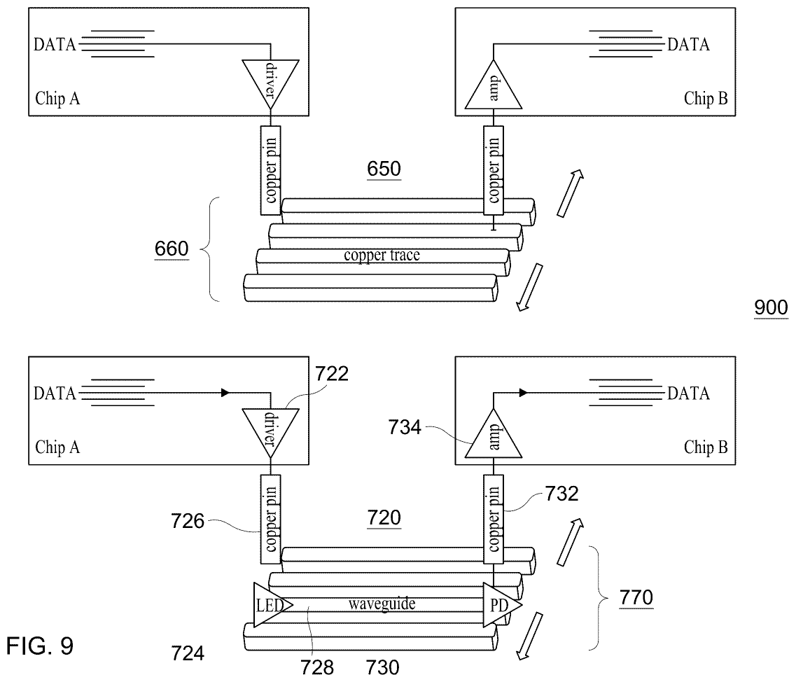

FIG. 9 represents a combination of photonic (NPCL) and electrical interposers/bridges wherein no SerDes is employed while driver and amplifier circuits are included in transmitting data through both photonic (NPCL) 720 and electrical 660 signal paths in the hybrid interposer 900.

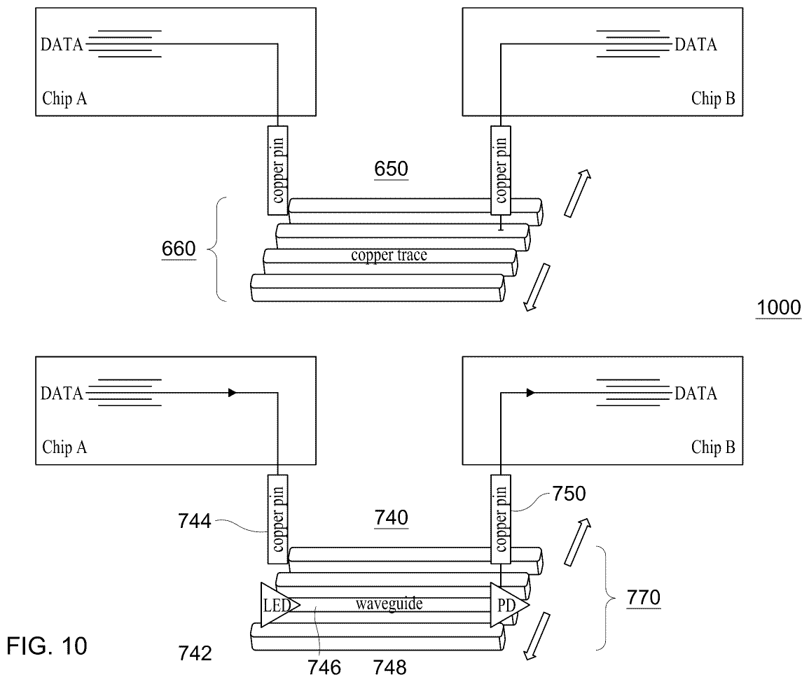

FIG. 10 represents a combination of photonic (NPCL) and electrical interposers/bridges wherein no SerDes or driver or amplifier circuits are employed in transmitting data through both photonic (NPCL) 740 and electrical 660 signal paths in the hybrid interposer 1000. In this embodiment the data is provided with sufficient energy per bit out of the drive stages of Chip A or Chip B to drive a signal into the input circuitry of the other chip with no amplification or other signal conditioning. It should be noted that other arrangements of NPCL and electrical interposers/bridges are feasible, for example serialized electrical bridges using amplifiers and drivers combined with directly driven (no serialization, no signal amplification) photonic communication.

In such arrangements, the planarity of the NPCL allows planar electrical interconnect to be fabricated above it in a “back-end of line” semiconductor fabrication process in the same way that CoWoS or EMIB or any other electrical interposers or bridges are formed. Electrical wires may be co-integrated with optical waveguides. Metal layers used to connect to light emitting devices and photodiodes in the NPCL may be used to form metal lines for the electric bridge/interposer.

NPCL is compatible with present and anticipated future interposers and bridges. In a hybrid interposer that combines both electrical and photonic interconnect layers, signals can be routed via either medium depending on the distance the signal must be propagated.

The input characteristics (voltage, impedance) of the NPCL may be designed (selected) to match those of the electrical signal paths. Then the same driver circuits used to send signals via electrical interposer/bridge lines can be used to send signals through NPCL signal lines.

The same transmitter circuit may be used to drive an optical path or an electrical path. Voltage and current to drive an optical source (LED or laser) is matched to the voltage and current that drives an electrical signal path. Typically, these might be 0.7 V and 1 mA.

The same receiver circuit may be used to receive a data signal from an optical path or an electrical path. Signal from a photodiode is equivalent to signal from an electrical interconnect and is sufficient to drive the first inverter stage of a receiver.

Ideally then, the optical interconnect has same input and output characteristics as the electrical interconnect. At the transmitters, the input impedances of the electric and photonic paths are matched within a tolerance that the various chipsets that communicate through the electric and photonic signal paths do not need to know if the signal path is electric or photonic. Similarly, at the receivers, the output impedances of the electric and photonic paths are matched within a tolerance that the various chipsets that communicate through the electric and photonic signal paths do not need to know if the signal path is electric or photonic.

Photonic signaling is, in one embodiment, non-return-to-zero (NRZ), single pole, and single wavelength. The light may be incoherent and broad spectrum. Lasers are not required to transmit photonic signals. Light emitting diodes with broad emission spectra are less sensitive to temperature variations which are inevitable if the die being interconnected by the NPCL are high performance compute dies such as GPUs or CPUs.

Electric interfaces in the electric interposer/bridge layers accept NRZ voltage inputs having voltages in the range 0.5 to 2.0 V. Similarly, photonic interfaces in the NPCL layer accept voltage inputs having voltages in the range 0.5 to 2.0 V.

All electric and photonic interfaces can accept the same data signals. The various chipsets that communicate through the electric and photonic signal paths do not need to know if the signal path is electric or photonic.

Moreover, photonic signal paths can pass over electrical signal lines with zero crosstalk. This provides an additional signal routing option to have signals from various die cross over, providing much greater flexibility in system-in-a-package layout design.

Both the electric and photonic signal paths can be configured such that they similarly accommodate UCIe signaling specifications which are currently being established.

The NPCL is electrically testable before package assembly and adheres to common layout pitches and rules. Having a pitch around 3-5 μm, the waveguides are easily compatible with current micro-bump pitches of around 40-60 μm and are also more closely compatible with projected hybrid bonding pitches (˜1 μm).

Thus, embodiments of the present invention provide a low-cost, low power, within-package short-and-long-distance interconnect with reduced placement restrictions, i.e., connections that can be anywhere on the respective die and can equally well connect dies that are near or far within the package while remaining synchronous.

What is claimed is:

1. An electronic device, comprising a plurality of semiconductor dies, each including a number of circuit blocks, and at least one interposer, the dies and a hybrid photonic-electric interposer located within a common package, the hybrid photonic-electric interposer comprising both a photonic part that includes photonic signal paths and an electrical part that includes electrical signal paths and configured so as to transport data between various ones of the circuit blocks of the dies through both the photonic and electrical signal paths.

2. The electronic device of claim 1, wherein the electrical signal paths and the photonic signal paths are formed in parallel planes in the hybrid photonic-electric interposer.

3. The electronic device of claim 1, wherein within one or more of the dies, those of the circuit blocks of the dies that communicate through the photonic signal paths are physically interspersed with others of the circuit blocks that communicate using the electrical signal paths.

4. The electronic device of claim 1, wherein light emitting devices, waveguides, and photodetectors of the photonic part of the interposer are coplanar.

5. The electronic device of claim 4, wherein the waveguides, light emitting devices and photodiodes have widths of approximately one micron.

6. The electronic device of claim 1, wherein the photonic part of the interposer is disposed underneath the electrical part of the interposer with photonic waveguides of the photonic part of the interposer arrayed under metal interconnect layers of the electrical part of the interposer, the photonic waveguides surrounded by a low refractive index dielectric.

7. The electronic device of claim 6, wherein the low refractive index dielectric is silicon dioxide.

8. The electronic device of claim 6, wherein a silicon oxide layer is disposed below the photonic waveguides, the silicon oxide layer being a buried oxide layer of a semiconductor-on-insulator substrate.

9. The electronic device of claim 1, wherein the photonic and electronic signal paths crossover one another within the hybrid photonic-electric interposer.

10. The electronic device of claim 1, wherein the photonic part of the interposer includes numerous parallel photonic signal paths sufficient to provide thousands or tens-of-thousands of point-to-point connections.

11. The electronic device of claim 1, wherein the photonic part of the interposer includes a light emitting diode arranged to transmit photonic signals according to a non-return-to-zero modulation scheme, said light emitting diode configured to be modulated directly by an electrical signal provided by a respective circuit block on a respective one of the dies.

12. The electronic device of claim 1, wherein the electrical signal paths are configured for short distance signaling between the circuit blocks.

13. The electronic device of claim 1, wherein the photonic signal paths are configured for connections between the circuit blocks of at least approximately 100 mm.

14. The electronic device of claim 1, wherein light emitting devices, waveguides, and photodetectors of the photonic part of the interposer are manufactured within a common process flow as metal wires that comprise the electrical interposer.

15. The electronic device of claim 1, wherein light emitting devices of the photonic part of the interposer are light emitting diodes (LEDs).

16. The electronic device of claim 1, wherein light emitting devices of the photonic part of the interposer are lasers.

17. The electronic device of claim 1, wherein the photonic part of the interposer includes:
light emitting devices configured to generate optical signals within a gain medium disposed locally within a semiconductor-on-insulator substrate, the light emitting devices configured to each be directly modulated by respective electrical signals to generate respective ones of the optical signals,
waveguides configured as single-wavelength point-to-point connections to route the respective optical signals to respective receivers, and
photodetectors configured as the respective receivers to detect the respective optical signals and to each directly drive a receiving stage in a receiving circuit.

18. The electronic device of claim 1, wherein the photonic part of the interposer includes:
light emitting devices configured to generate optical signals within a gain medium disposed locally within a semiconductor-on-insulator substrate, the light emitting devices configured to each be directly modulated by respective electrical signals provided by output stages of CMOS logic circuits to generate respective ones of the optical signals,
waveguides configured as single-wavelength point-to-point connections to route the respective optical signals to respective receivers, and
photodetectors configured as the respective receivers to detect the respective optical signals and to each directly drive a first stage of a CMOS circuit.

19. The electronic device of claim 1, wherein the electrical part of the interposer overlies the photonic part of the interposer.

20. The electronic device of claim 1, wherein at least one of the dies comprises memory.

21. A hybrid photonic-electric interposer, comprising an electrical part that includes electrical signal paths and a photonic part that includes photonic signal paths, the photonic part of the interposer including a plurality of sets of light emitting devices, waveguides, and photodetectors, wherein in each one of said sets, the respective light emitting device, waveguide, and photodetector are coplanar with one another.

22. The hybrid photonic-electric interposer of claim 21, wherein the photonic part of the interposer is disposed underneath the electrical part of the interposer with the waveguides of the photonic part of the interposer arrayed under metal interconnect layers of the electrical part of the interposer, the waveguides being surrounded by a low refractive index dielectric.

23. The hybrid photonic-electric interposer of claim 21, wherein the light emitting devices of the photonic part of the interposer are light emitting diodes and each of said light emitting diodes is configured to be modulated directly by an electrical signal provided by output stages of CMOS logic circuits to transmit photonic signals according to a non-return-to-zero modulation scheme.

24. The hybrid photonic-electric interposer of claim 21, wherein the electrical signal paths and the photonic signal paths are formed in parallel planes in the hybrid photonic-electric interposer.
